(19) United States
(12) Patent Application Publication
(10) Pub. No.: US 2007/0039923 A1
(43) Pub. Date: Feb. 22, 2007

(54) METHOD FOR PREVENTING CHARGE-UP IN PLASMA PROCESS AND SEMICONDUCTOR WAFER MANUFACTURED USING SAME

(75) Inventor: Yong-Sam KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Suwon-si (KR)

(21) Appl. No.: 11/381,218

(22) Filed: May 2, 2006

(30) Foreign Application Priority Data
Aug. 17, 2005 (KR) 10-2005-0075439

(51) Int. Cl. C23F 1/00; H01L 29/00; H01L 21/302

(52) U.S. Cl. 216/67; 438/710; 257/499

(57) ABSTRACT

A method for preventing plasma charge-up of a semiconductor wafer includes defining a semiconductor chip region and a scribe line region on a semiconductor wafer, forming an interlayer insulating layer pattern on the wafer, the interlayer insulating layer pattern exposing the scribe line region, plasma etching the interlayer insulating layer pattern to form a contact hole that exposes the semiconductor chip region, and during the plasma etching, discharging an electric charge generated by the plasma etching through the scribe line region.

### CROSS-REFERENCE TO RELATED APPLICATIONS

This application claims priority from Korean Patent Application No. 10-2005-75439, which was filed on 17 Aug. 2005. Korean Patent Application No. 10-2005-75439 is incorporated by reference in its entirety.

### BACKGROUND

1. Technical Field

This disclosure relates to a method for preventing charge-up in a plasma process and a semiconductor wafer manufactured thereby, and more particularly, to a method for preventing charge-up in a plasma process by which electric charge generated during a plasma process is discharged through a scribe line region, and a semiconductor wafer manufactured thereby.

2. Discussion of the Related Art

A semiconductor device manufacturing process typically includes deposition of a thin film or layer on the surface of a semiconductor wafer. Another layer may be formed between the semiconductor wafer and the thin film. One method to carry out the deposition of the thin film or layer is using a Chemical Vapor Deposition (CVD) process. The CVD process may include a chemical reaction of reactants or vaporous chemicals. The chemicals or reactants may include a desired element to be deposited on a substrate or another layer. Reactant gases flow into a reaction chamber or reactor, are broken-down on a heated surface, and react to form a desired thin film or layer.

There are three kinds of CVD process which may be used for forming a thin film or layer. These are atmospheric pressure CVD (APCVD), low pressure CVD (LPCVD), and plasma-enhanced CVD (PECVD). APCVD and LPCVD differ in pressure but both use thermal energy to obtain a desired chemical reaction. Unlike the APCVD and LPCVD processes that depend on heat to start and maintain a chemical reaction, PECVD uses an RF-induced glow discharge to transfer energy to the reactant gases. Use of RF-induced glow discharge enables a wafer to be processed at a lower temperature than APCVD and LPCVD systems. The PECVD process is may be used to deposit a thin layer such as a silicon oxide layer, a silicon nitride layer, and a metal layer.

A plasma etching process may be used to precisely etch a fine pattern when layers obtained by the PECVD or other processes are etched. The plasma etching process includes placing a wafer having a desired layer in a flat etching chamber, supplying an etchant including oxygen or fluorine into the chamber, applying high-frequency energy to ionize the etchant, and reacting the ionized oxygen or fluorine with a layer of the wafer surface. This process may be used to keep the wafer clean after etching because most products are in gas phase and thus may be simply removed, for example, by an exhausting process.

However, reaction products that include a large amount of electric charge may accumulate on the surface of the exposed wafer in plasma etching. While, such reaction products may be removed to some degree through the exhausting process, etc., most electric charges are trapped and accumulate near a conductive pattern, thereby causing a charge-up phenomenon. This leads to arcing of the accumulated electric charge due to stress between the narrow conductive patterns. Therefore, a technique for preventing electric charge from accumulating in the plasma etching process is needed.

Embodiments of the invention address these and other disadvantages of the related art.

### SUMMARY

According to some embodiments, a method of preventing charge-up in a plasma process is capable of reducing accumulation of electric charge on the surface of a semiconductor wafer during a plasma etching process.

According to some embodiments, a semiconductor wafer is capable of reducing accumulation of electric charge on its surface during a plasma etching process.

### BRIEF DESCRIPTION OF THE DRAWINGS

The foregoing and other objects, features and advantages of the invention will be apparent from the more particular description of exemplary embodiments of the invention, as illustrated in the accompanying drawings. The drawings are not necessarily to scale, emphasis instead being placed upon illustrating the principles of the invention.

FIG. 1 is a plan diagram that illustrates part of a semiconductor wafer in accordance with some embodiments of the invention.

FIGS. 2A through 2M are cross-sectional diagrams, taken along line I-I′ of FIG. 1, which illustrate exemplary processes in a method for preventing charge-up in a plasma process in accordance with some embodiments of the invention.

FIG. 3 is a plan diagram illustrating part of a semiconductor wafer in accordance with some embodiments of the invention.

FIGS. 4A through 4M are cross-sectional diagrams, taken along line II-II′ of FIG. 3, which illustrate exemplary processes in a method for preventing charge-up in a plasma process in accordance with some embodiments of the invention.

### DETAILED DESCRIPTION

The invention will now be described more fully hereinafter with reference to the accompanying drawings, in which exemplary embodiments of the invention are shown.

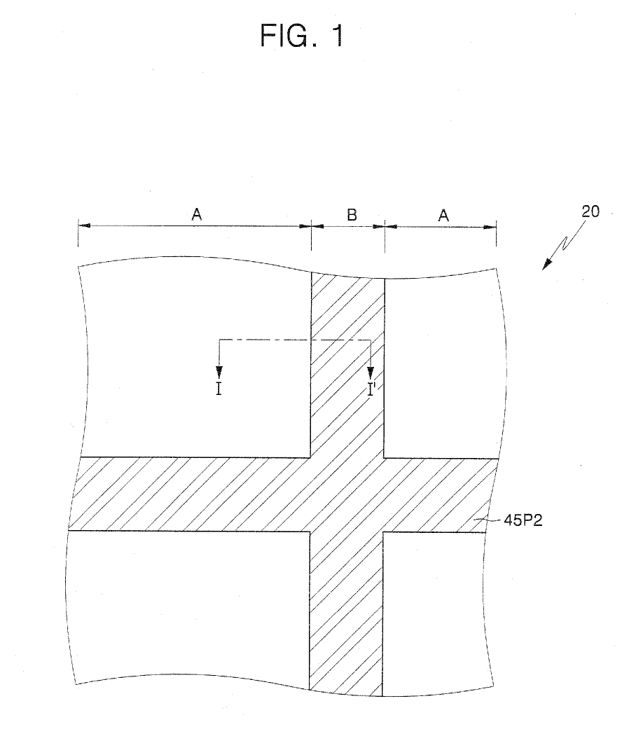

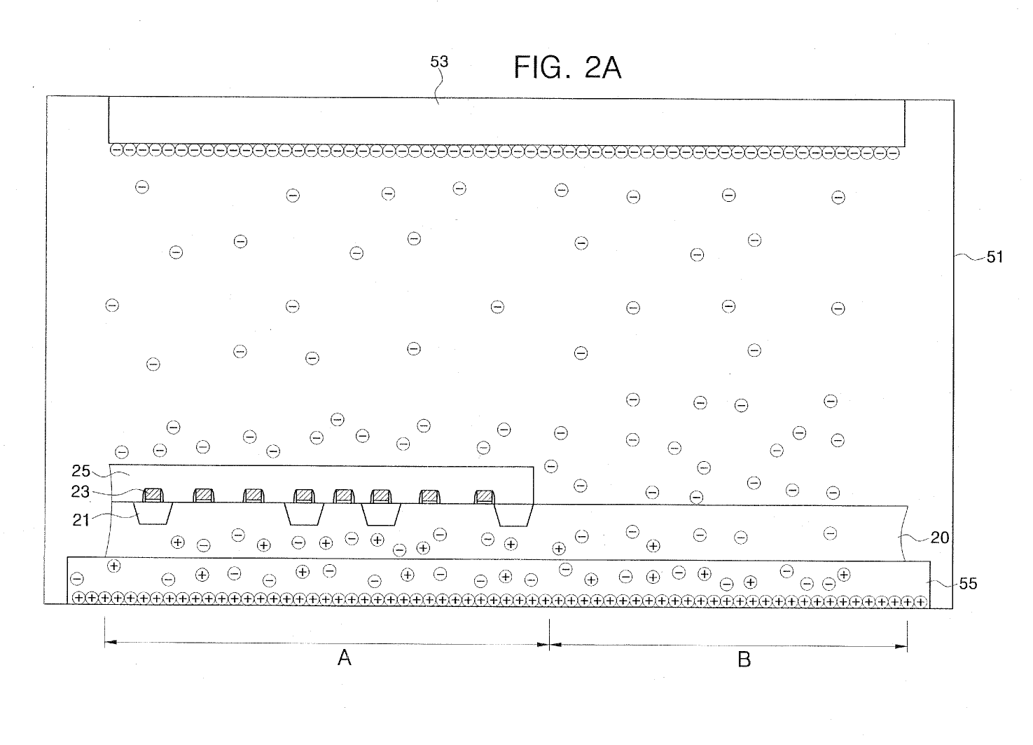

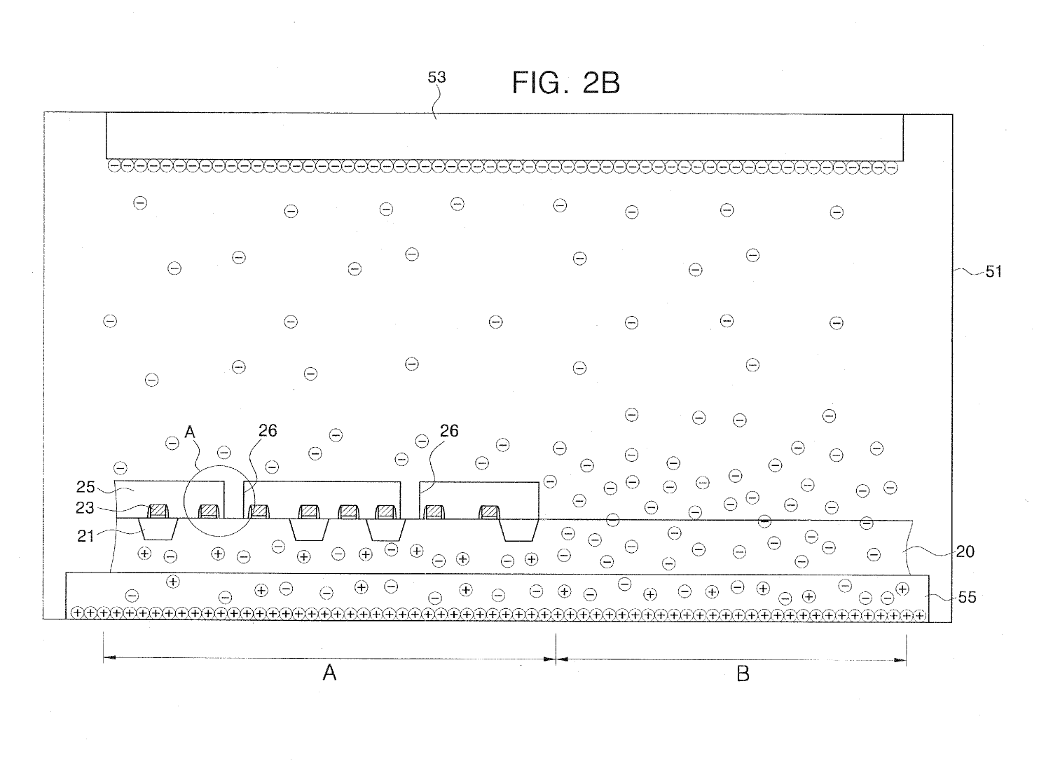

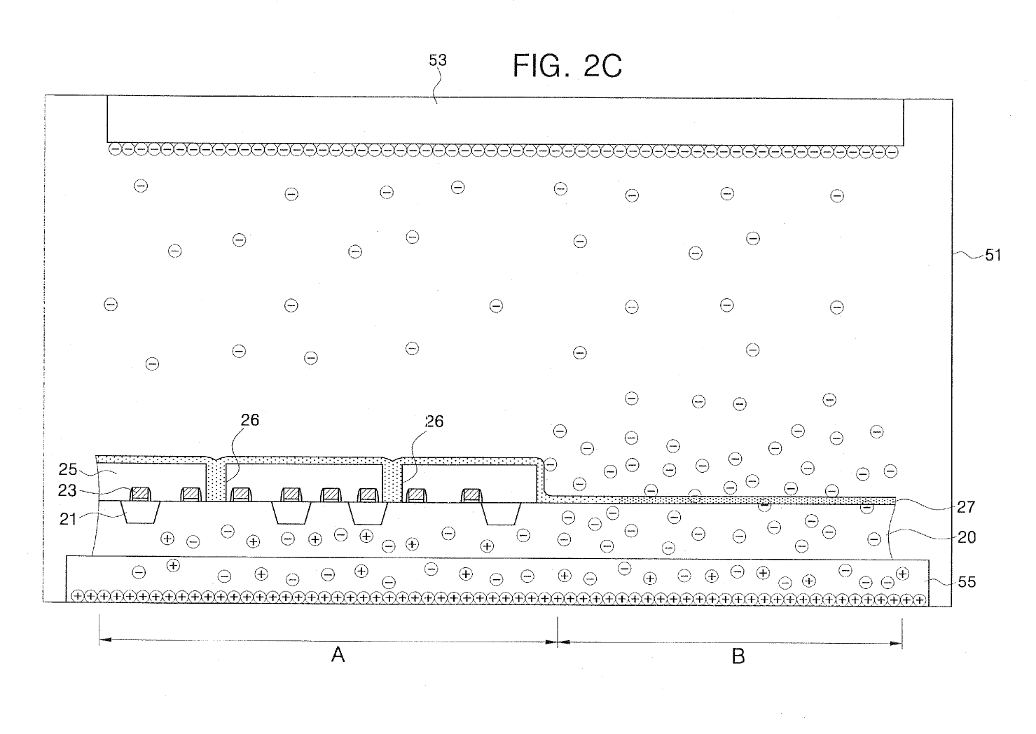

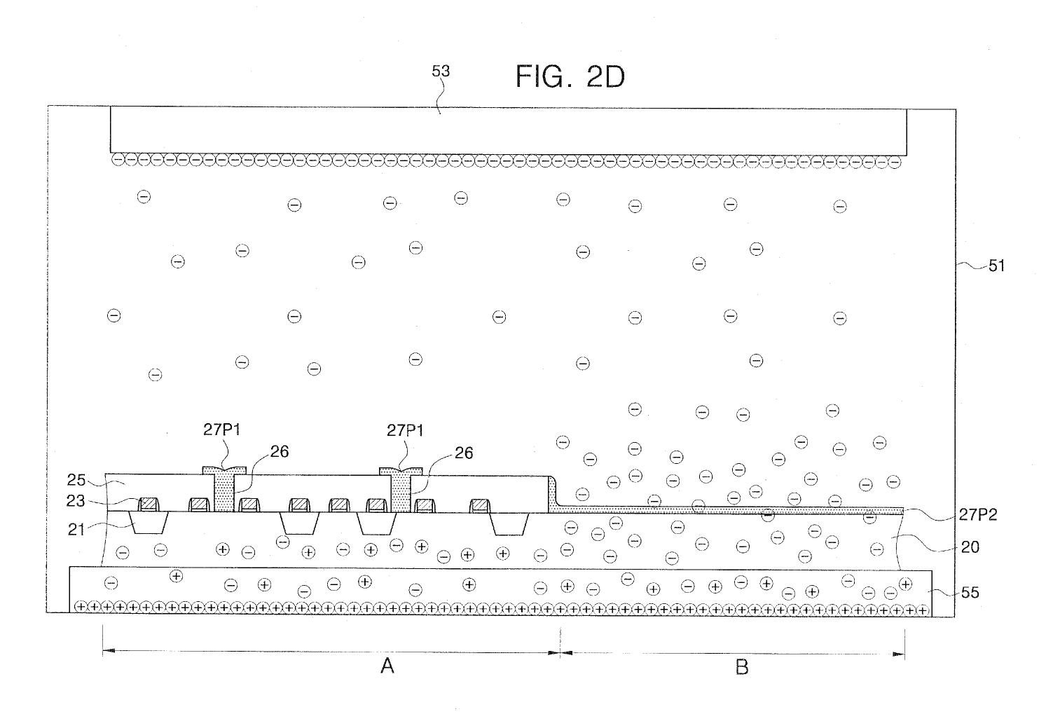

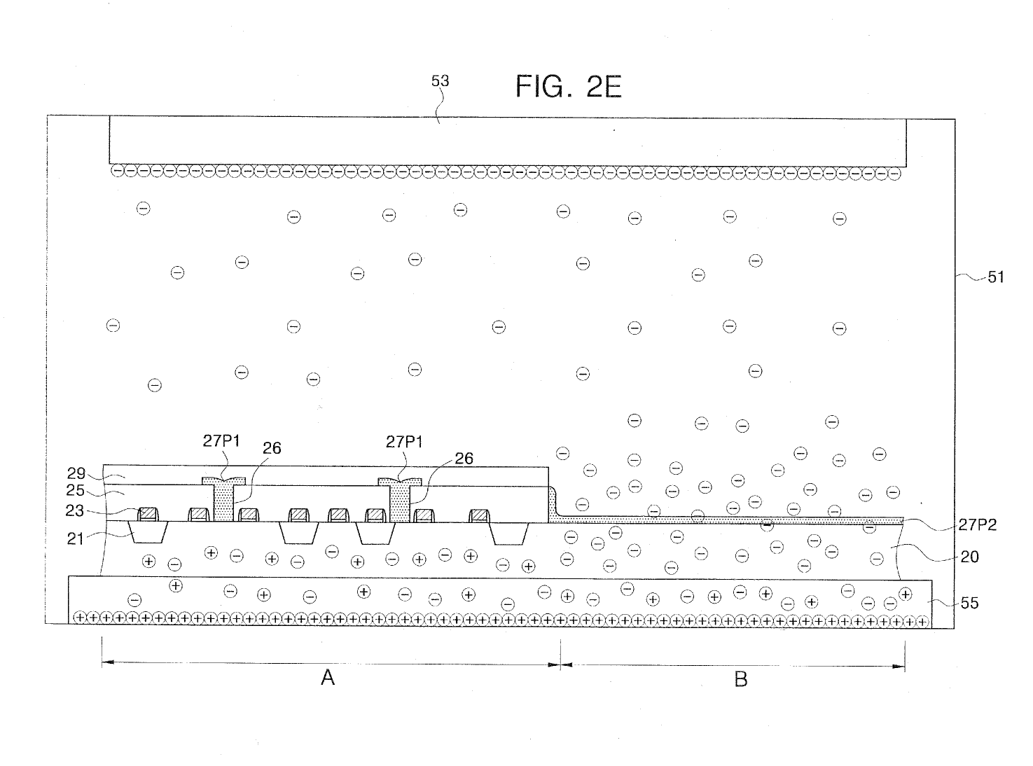

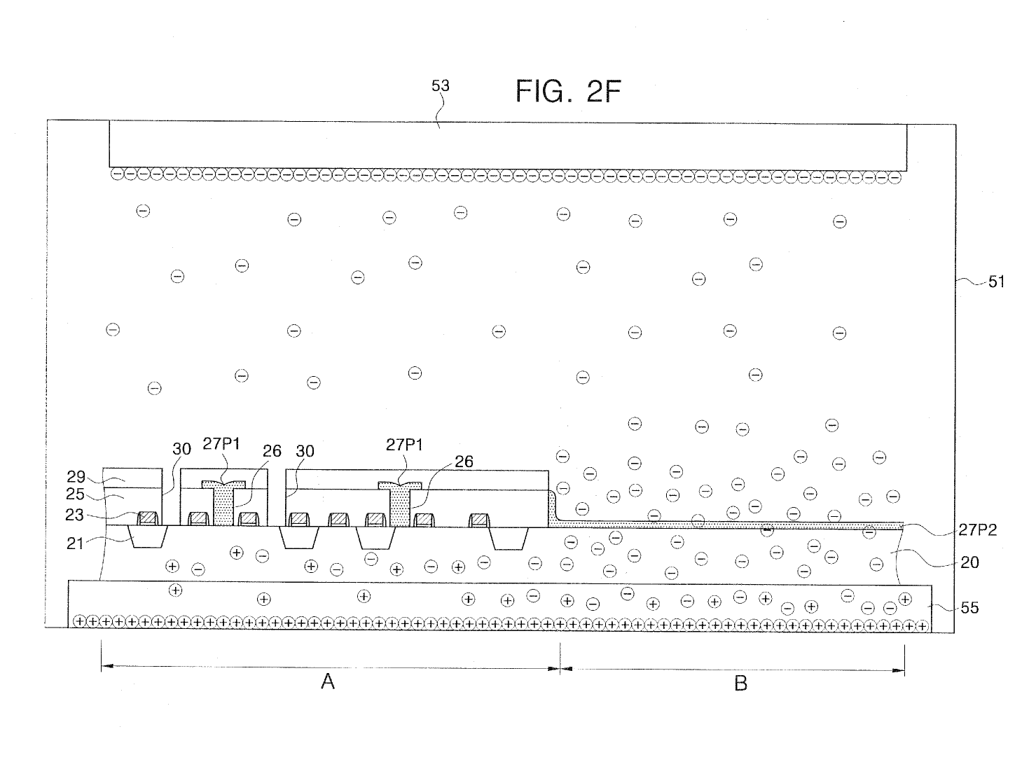

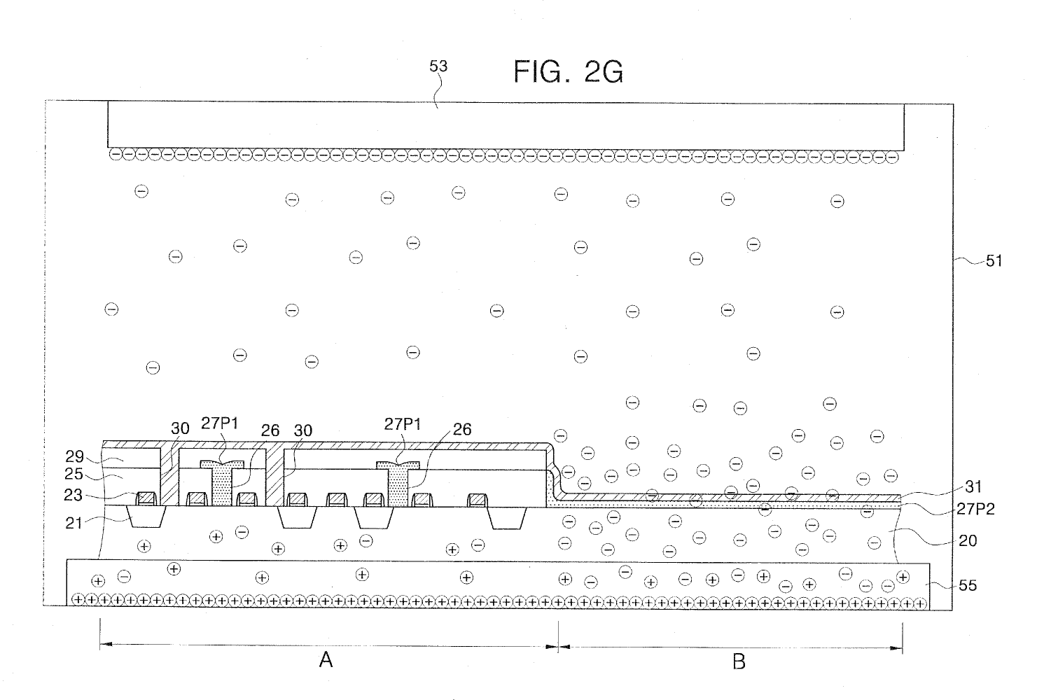

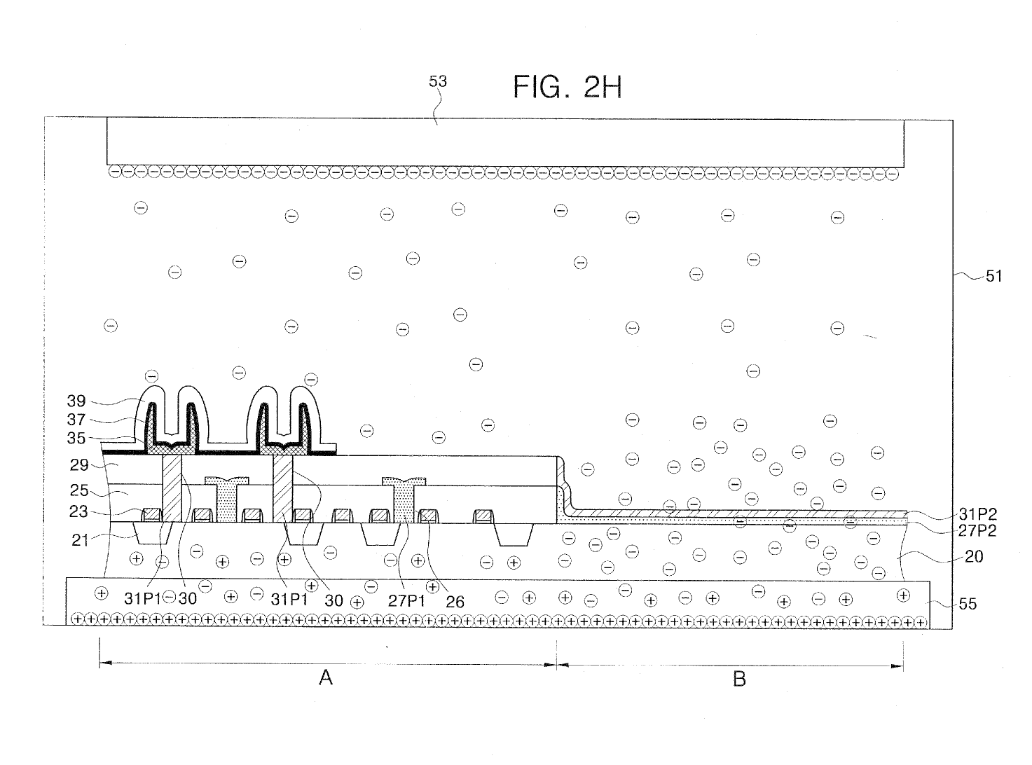

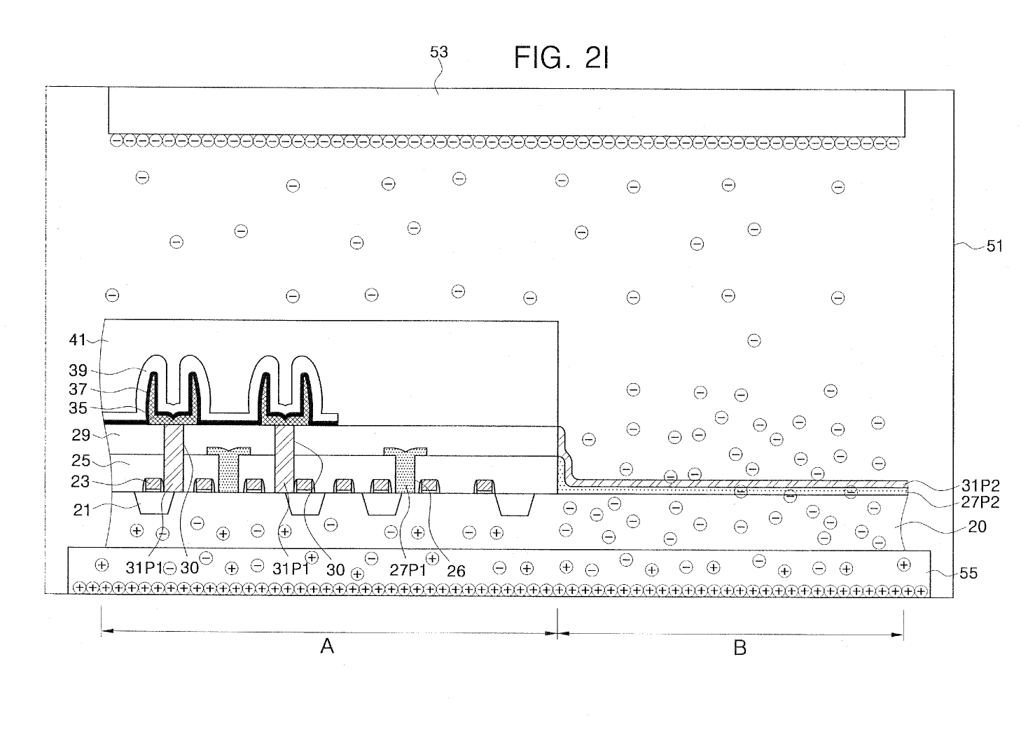

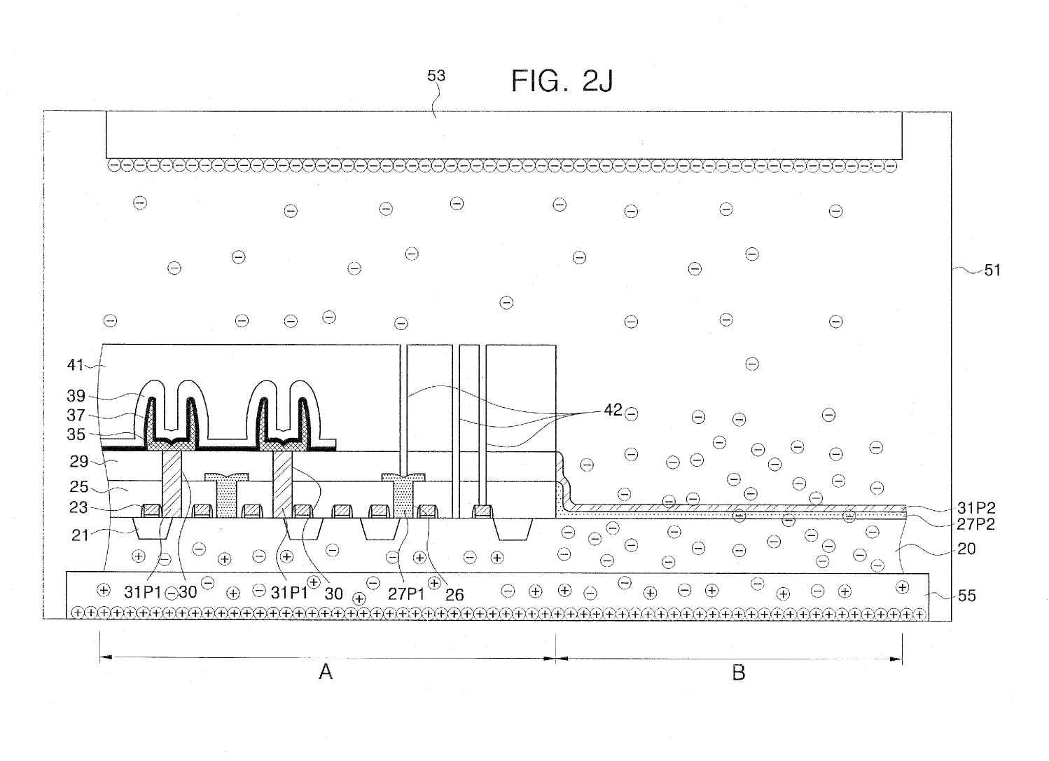

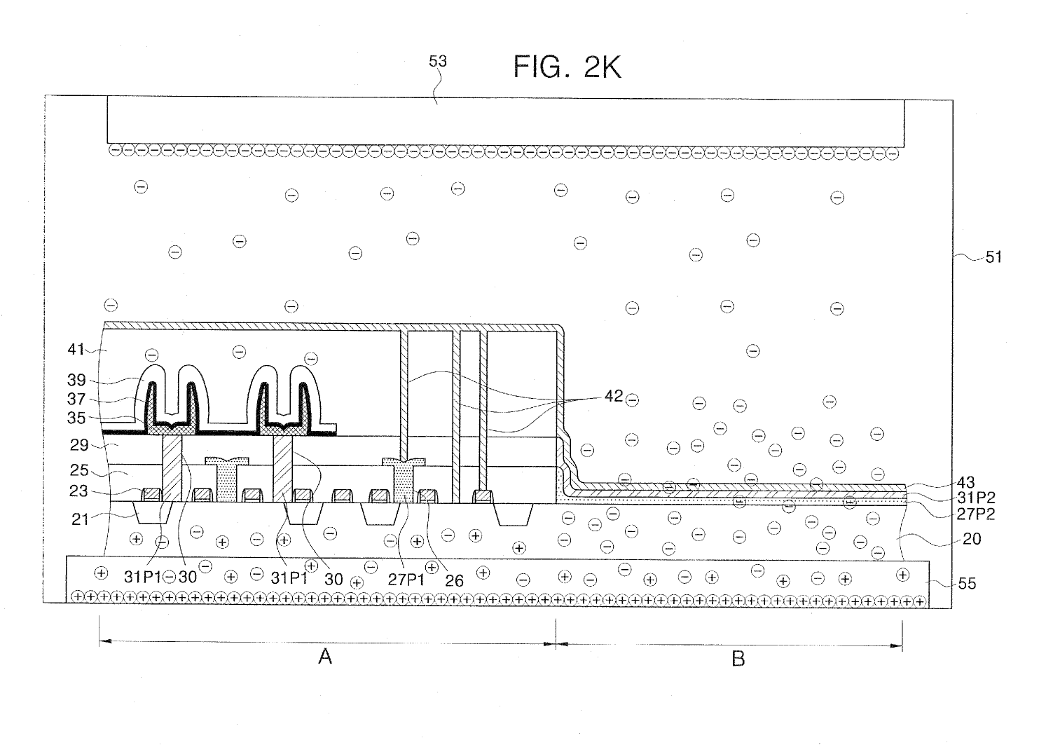

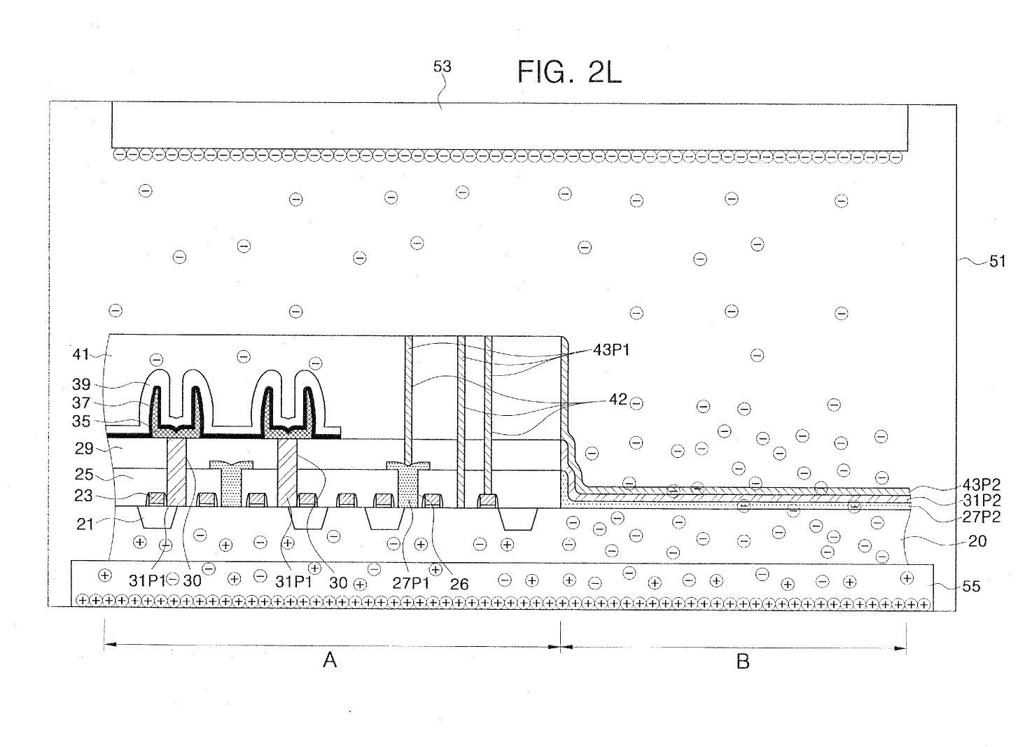

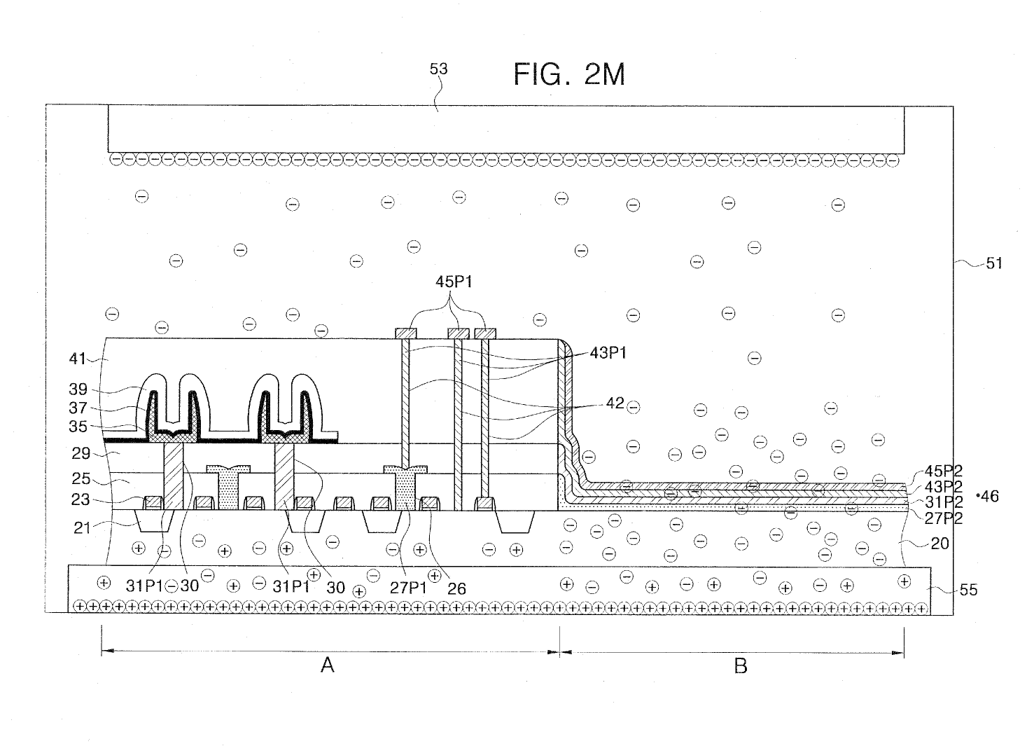

FIG. 1 is a plan diagram that illustrates part of a semiconductor wafer in accordance with some embodiments of the invention. FIGS. 2A through 2M are cross-sectional diagrams, taken along line I-I′ of FIG. 1, which illustrate exemplary processes in a method for preventing charge-up in a plasma process in accordance with some embodiments of the invention.

As shown in FIG. 1, semiconductor chip regions A and scribe line regions B adjacent to the semiconductor chip regions are defined on a semiconductor wafer 20. The semiconductor wafer 20 has an interlayer insulating layer (not illustrated) that covers the semiconductor chip regions A and exposes the scribe line regions B. A conductive pattern (not illustrated) is disposed to contact a part of the semiconductor chip regions A through the interlayer insulating layer, and conductive auxiliary patterns 46 are disposed to cover the scribe line regions B. The insulating layer and the conductive pattern/conductive auxiliary patterns 46 are sequentially stacked.

A method of preventing plasma charge-up of the semiconductor wafer according to some embodiments of the invention will now be described.

First, a semiconductor wafer 20 is provided and semiconductor chip regions A and scribe line regions B are defined as illustrated in FIG. 2A. The wafer 20 has isolation layers 21 formed by a well-known STI (Shallow Trench Isolation) process. Gates 23 and sources/drains are formed on the wafer having the isolation layers 21. Here, the sources/drains are omitted for convenience. The isolation layers 21 and the gates 23 are selectively formed on the wafer of the semiconductor chip region A.

A first interlayer insulating layer is formed on the semiconductor wafer having the gates 23 in a plasma process chamber 51. Upper and lower electrodes 53 and 55 are disposed in the plasma process chamber 51 at regular intervals. The semiconductor wafer having the gates 23 is disposed on the lower electrode 55, and deposition gas and high-frequency energy are supplied into the plasma process chamber 51. The deposition gas is ionized to react with a surface layer of the wafer by the high-frequency energy, thereby forming the first interlayer insulating layer. The first interlayer insulating layer is formed of an HDP (High Density Plasma) oxide layer. The illustrated embodiments give an example of forming the first interlayer insulating layer of the HDP oxide layer. However, the first interlayer insulating layer may be formed of an HTO (High Temperature Oxide) layer instead. Alternatively, some other oxide layers may be utilized for the first interlayer insulating layer.

A first interlayer insulating layer pattern 25 is formed on the semiconductor wafer having the gates 23 by selectively etching the first interlayer insulating layer in the plasma process chamber 51. The first interlayer insulating layer pattern 25 is formed to cover the semiconductor chip regions A of the wafer and expose the scribe line regions B of the wafer. The selective etching of the first interlayer insulating layer may be performed by a plasma etching process in the plasma process chamber 51 or by some other known etching processes.

As shown in FIG. 2B, the first interlayer insulating layer pattern 25 is selectively etched again in the plasma process chamber 51 to form first contact holes 26 exposing a prescribed area of the wafer in the semiconductor chip regions A. Here, during etching the interlayer insulating layer pattern 25, a large amount of electric charge generated by the plasma etching process is discharged through the exposed scribe line regions B of the wafer. Therefore, accumulation of electric charge near the conductive gates 23 in the semiconductor chip regions A may be largely prevented.

As shown in FIG. 2C, a first conductive layer 27 is formed on the wafer having the first contact holes 26. The first conductive layer 27 may be formed by a PECVD process. In the case of forming the first conductive layer 27 by the PECVD process, a large amount of electric charge generated by the process may be discharged through the first conductive layer 27 in the scribe line region B. The first conductive layer 27 may include a tungsten (W) layer. Before forming the first conductive layer 27, a barrier metal layer (not illustrated) may be formed. The barrier metal layer may be formed by the PECVD process and may include a TiN layer.

As shown in FIG. 2D, by selectively etching the first conductive layer with plasma, bit lines 27P1 covering the first contact holes 26 are formed on the wafer in the semiconductor chip regions A, and first conductive auxiliary patterns 27P2 are formed covering the wafer in the scribe line regions B. Most electric charge generated by the plasma etching process of the first conductive layer may be discharged to a lower portion of the wafer through the first conductive layer in the scribe line regions B before the entire first conductive layer is etched. Therefore, accumulation of large quantities of electric charge on the wafer in the semiconductor chip regions A may be prevented.

Referring to FIG. 2E, a second interlayer insulating layer is formed on the wafer having the bit lines 27P1 and the first conductive auxiliary patterns 27P2. The second interlayer insulating layer, like the first interlayer insulating layer, is formed of an oxide layer including an HTO layer and an HDP oxide layer. The second interlayer insulating layer is etched to form the second interlayer insulating layer pattern 29, which covers the semiconductor chip regions A of the wafer and exposes the first conductive auxiliary patterns 27P2 of the scribe line regions B. The etching of the second interlayer insulating layer may be etched by plasma etching in the plasma process chamber 51 or by some other known etching processes.

As shown in FIG. 2F, the second interlayer insulating layer pattern 29 is etched with plasma again in the plasma process chamber to form second contact holes 30 exposing a part of the semiconductor chip regions A of the wafer. At this time, quantities of electric charge generated during the plasma etching of the second interlayer insulating layer pattern 29 are discharged to a lower portion of the wafer through the first conductive auxiliary patterns 27P2 of the scribe line regions B. Thus, accumulation of a large amount of electric charge in the semiconductor chip regions A of the wafer may be prevented.

As shown in FIG. 2G, a second conductive layer 31 is formed on the wafer having the second contact hole 30. The second conductive layer 31 may include a multi-crystalline silicon layer or a metal layer. The metal layer may be formed by a PECVD process.

As shown in FIG. 2H, the second conductive layer is etched with plasma to form buried contact plugs 31P1 covering the second contact holes 30 of the semiconductor chip regions A, and second auxiliary patterns 31P2 covering sidewalls of the second interlayer insulating layer pattern 29 and the first conductive auxiliary patterns 27P2 of the scribe line regions B.

As shown in FIG. 2I, a capacitor is made by sequentially forming a storage node 35, a dielectric layer 37 and a plate 39 on the wafer having the buried contact plugs 31P1 and the second conductive auxiliary patterns 31P2. At least one part of the storage node 35 is electrically connected to the buried contact plugs 31P2. A third interlayer insulating layer is formed on the wafer having the capacitor. The third interlayer insulating layer pattern 41 is formed on the wafer having the capacitor by selectively plasma etching the third interlayer insulating layer in the plasma process chamber 51. The third interlayer insulating layer pattern 41 is formed to cover the semiconductor chip regions A of the wafer and expose the second conductive auxiliary patterns 31P2. The selective etching of the third interlayer insulating layer may be performed by plasma etching in the plasma process chamber 51 or some other known etching processes.

As shown in FIG. 2J, the third interlayer insulating layer pattern 41 is selectively etched to form third contact holes 42 exposing the bit lines 27P1, a part of the wafer, and the gates 23. At this time, a large amount of electric charge generated by the plasma etching of the third interlayer insulating layer pattern 41 is discharged to a lower portion of the wafer through the first and second conductive auxiliary patterns 27P2 and 31P2 disposed in the scribe line regions B. Thus, accumulation of a large amount of electric charge generated by the plasma etching of the third interlayer insulating layer pattern 41 on the wafer in the semiconductor chip regions A may be prevented.

As shown in FIG. 2K, a fourth conductive layer 43 is formed on the wafer having the third contact holes 42. The fourth conductive layer 43 may be formed by a PECVD process. The fourth conductive layer 43 may include a metal layer.

As shown in FIG. 2L, the fourth conductive layer 43 is etched with plasma to form plugs 43P1 covering each of the third contact holes 42, and third conductive auxiliary patterns 43P2 covering the second conductive auxiliary patterns 31P2 and sidewalls of the third interlayer insulating layer pattern 41 in the scribe line regions B.

As shown in FIG. 2M, a fourth conductive layer (not illustrated) is formed on the wafer having the plugs 43P1 and the third auxiliary patterns 43P2. The fourth conductive layer is etched with plasma to form metal interconnections 45P1 covering the plugs 43P1 in the semiconductor chip regions A, and fourth conductive auxiliary patterns 45P2 covering the third auxiliary patterns 43P2 in the scribe line regions B. Meanwhile, reference numeral 46 in FIG. 2M collectively denotes the first conductive auxiliary patterns 27P2, the second conductive auxiliary patterns 31P2, the third conductive auxiliary patterns 43P2, and the fourth conductive auxiliary patterns 45P2.

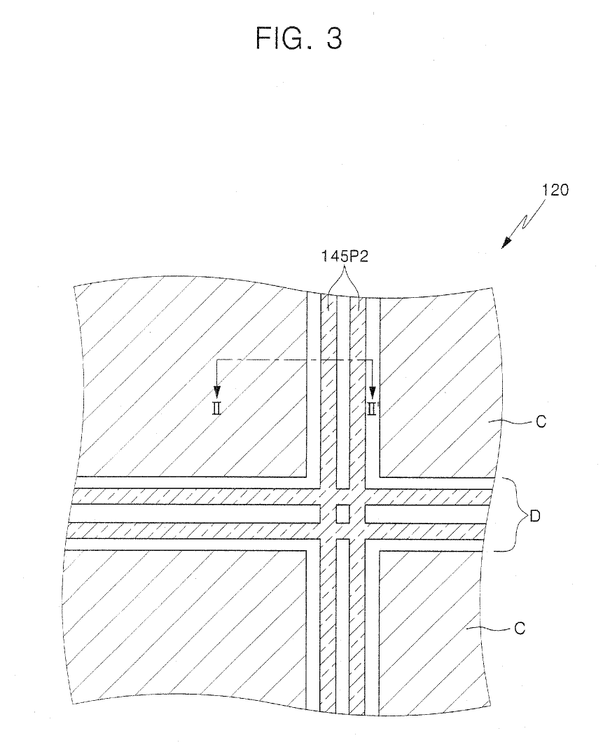

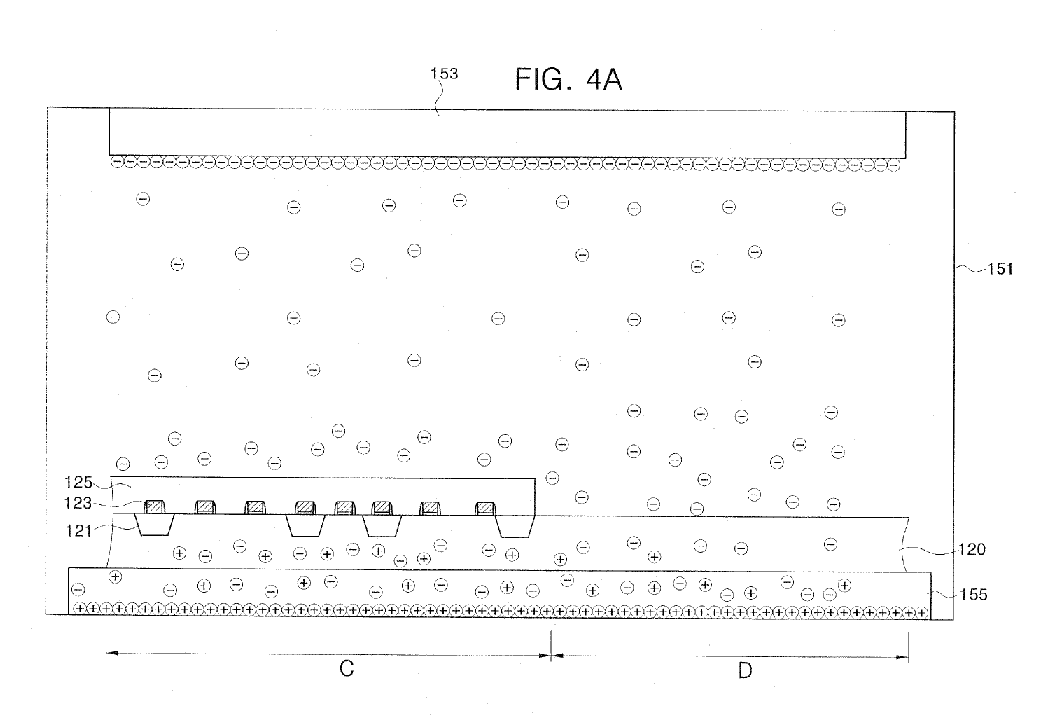

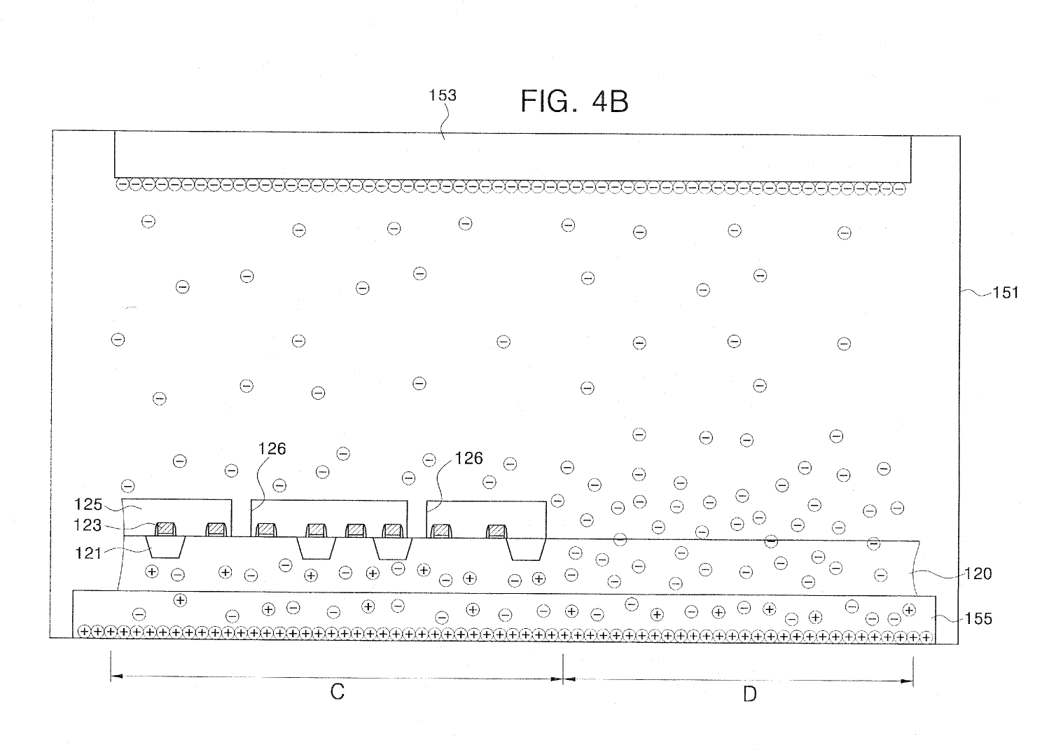

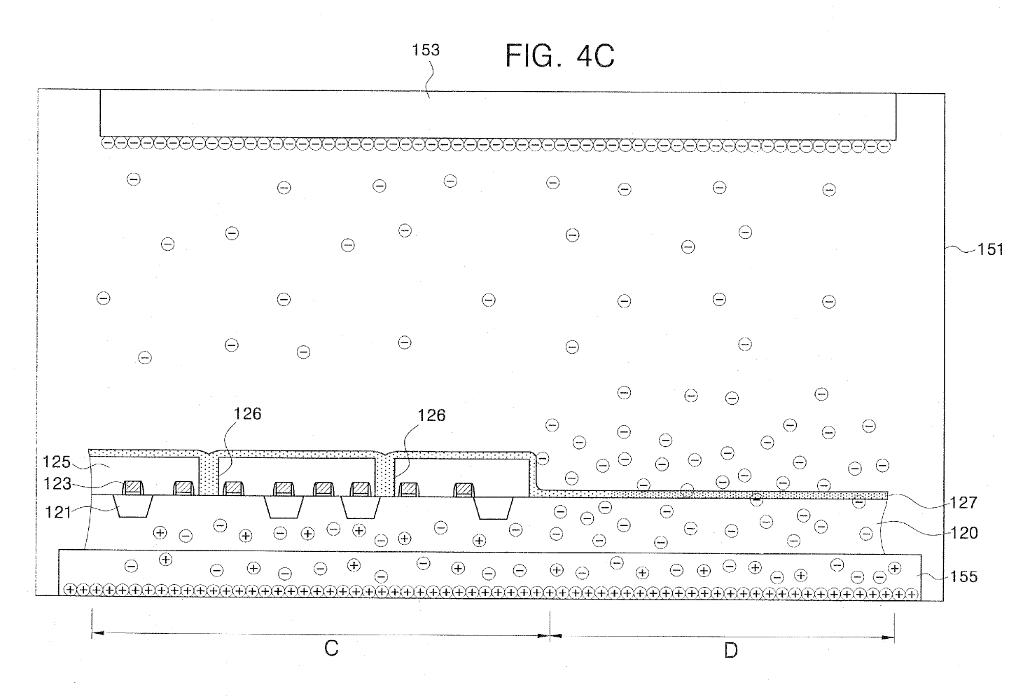

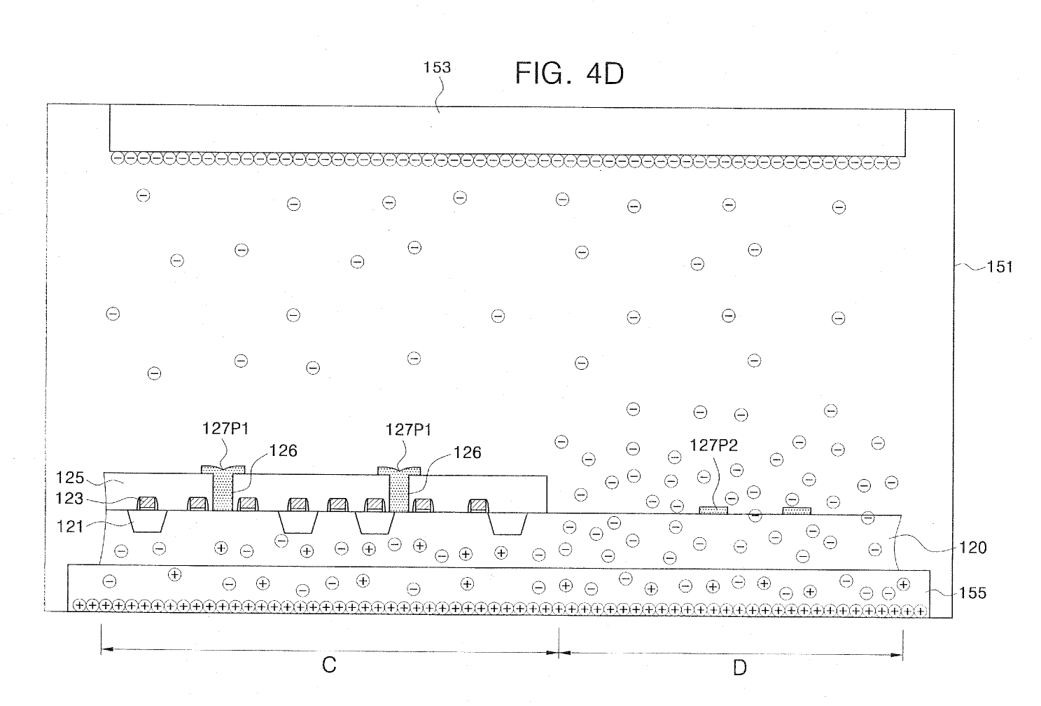

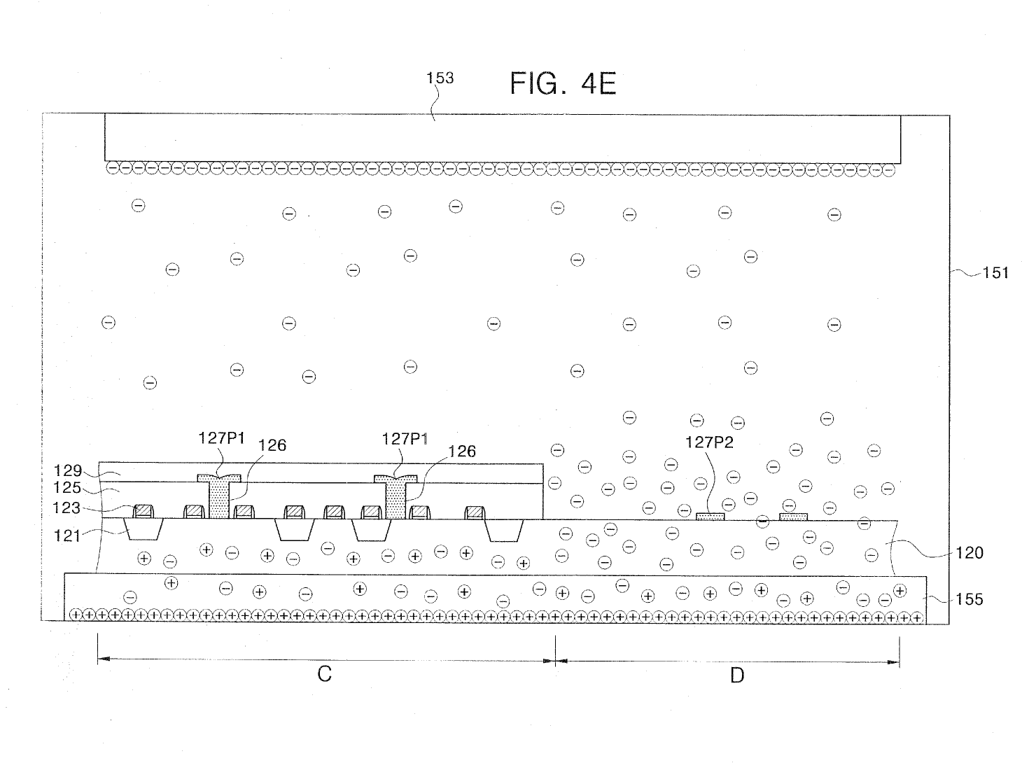

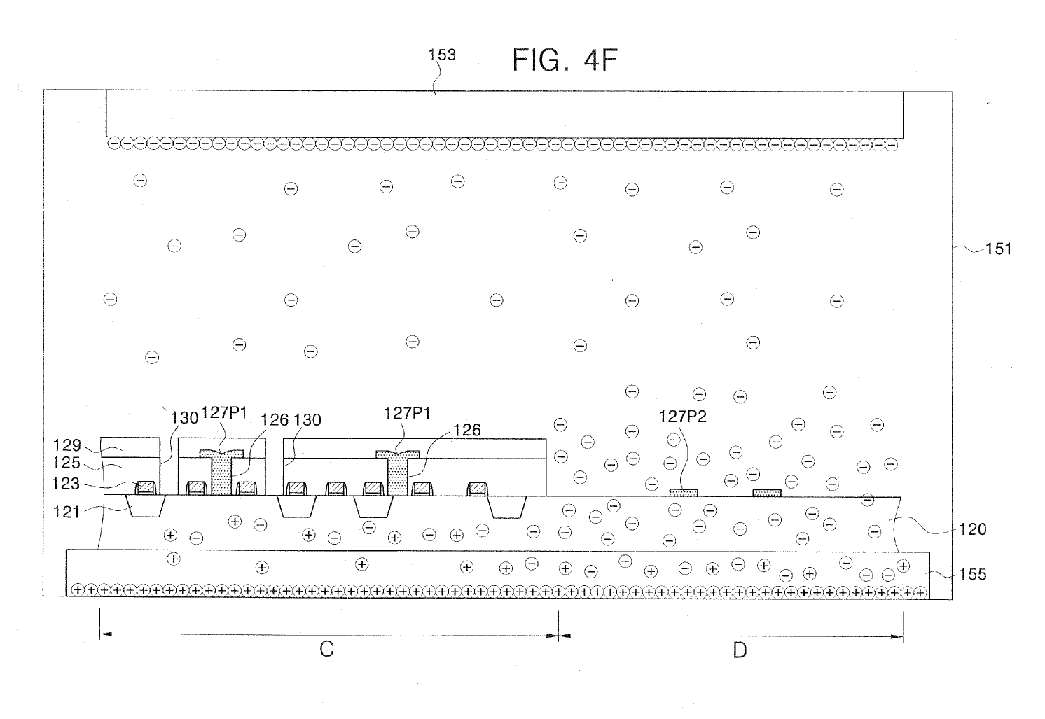

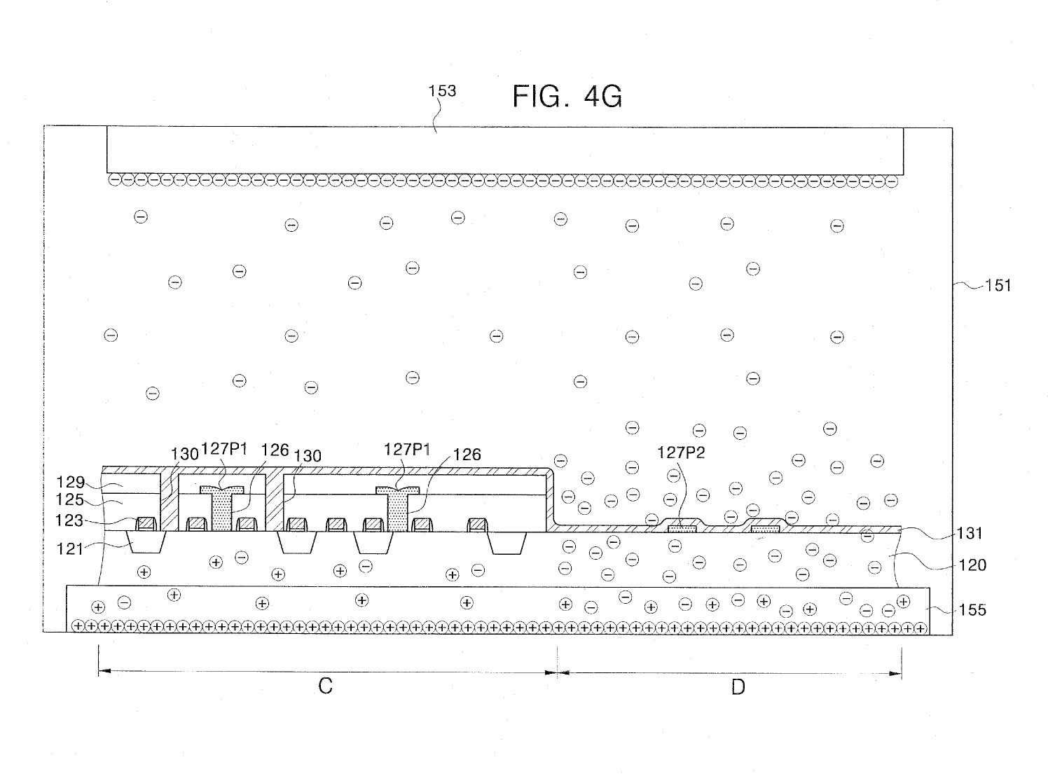

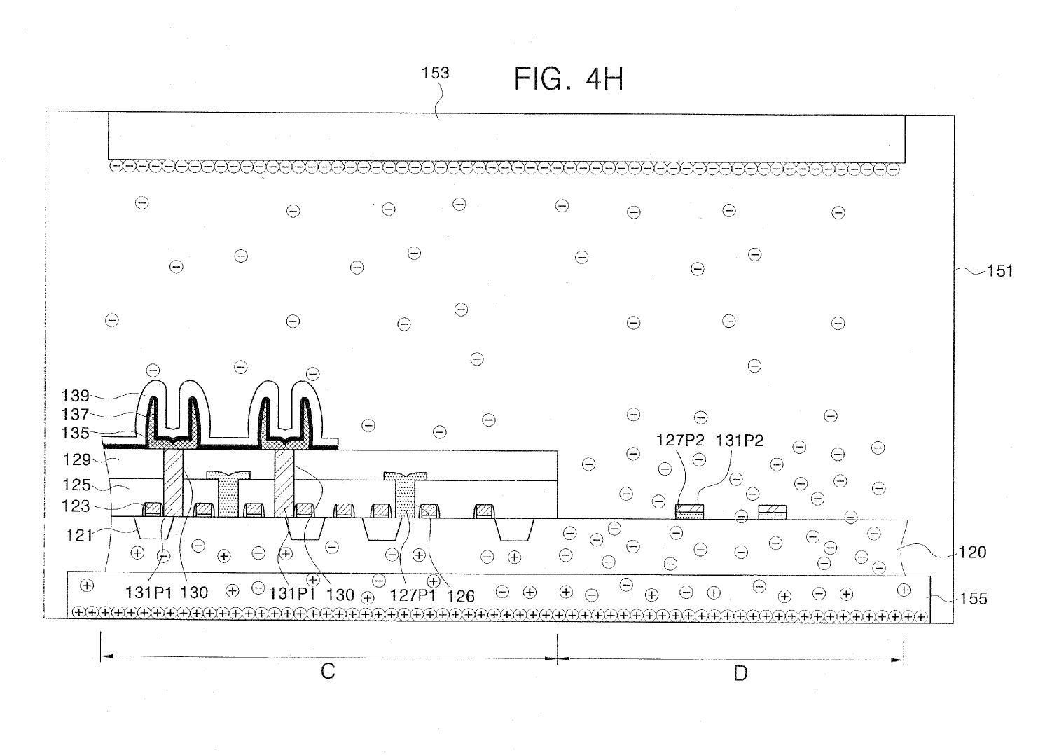

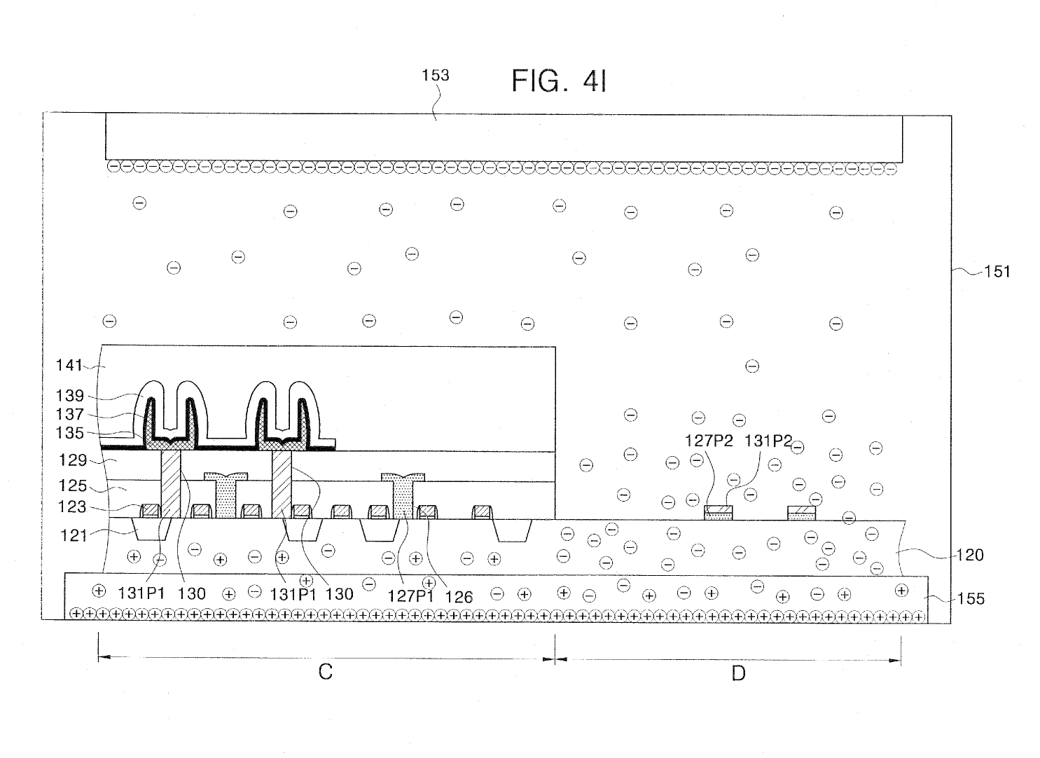

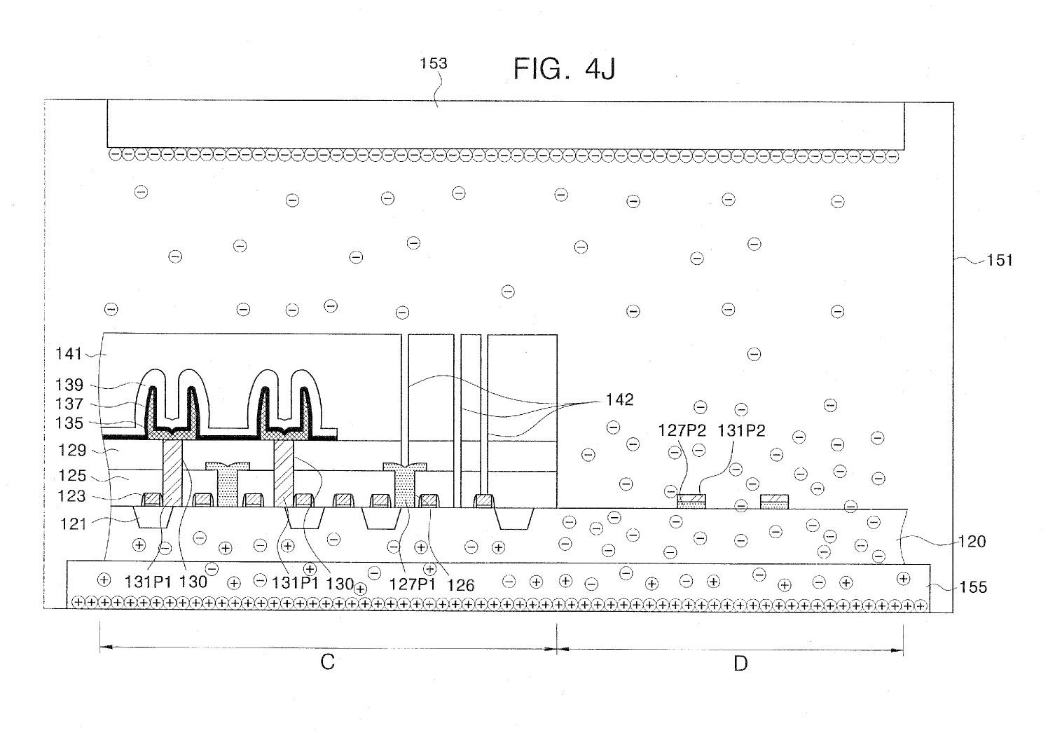

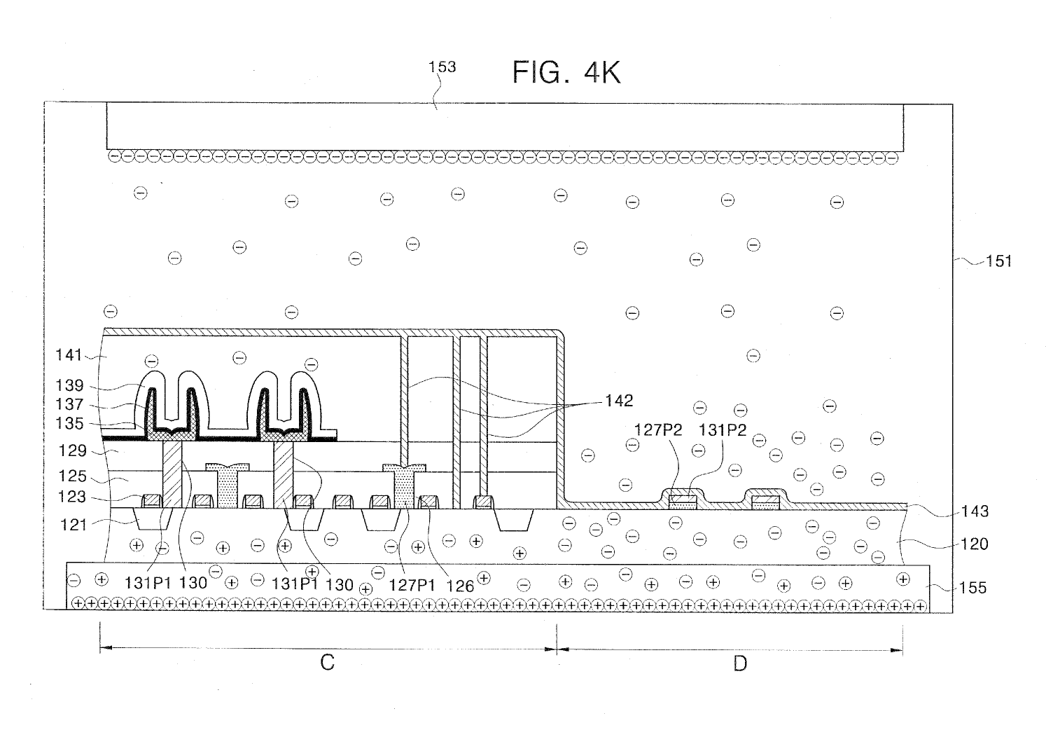

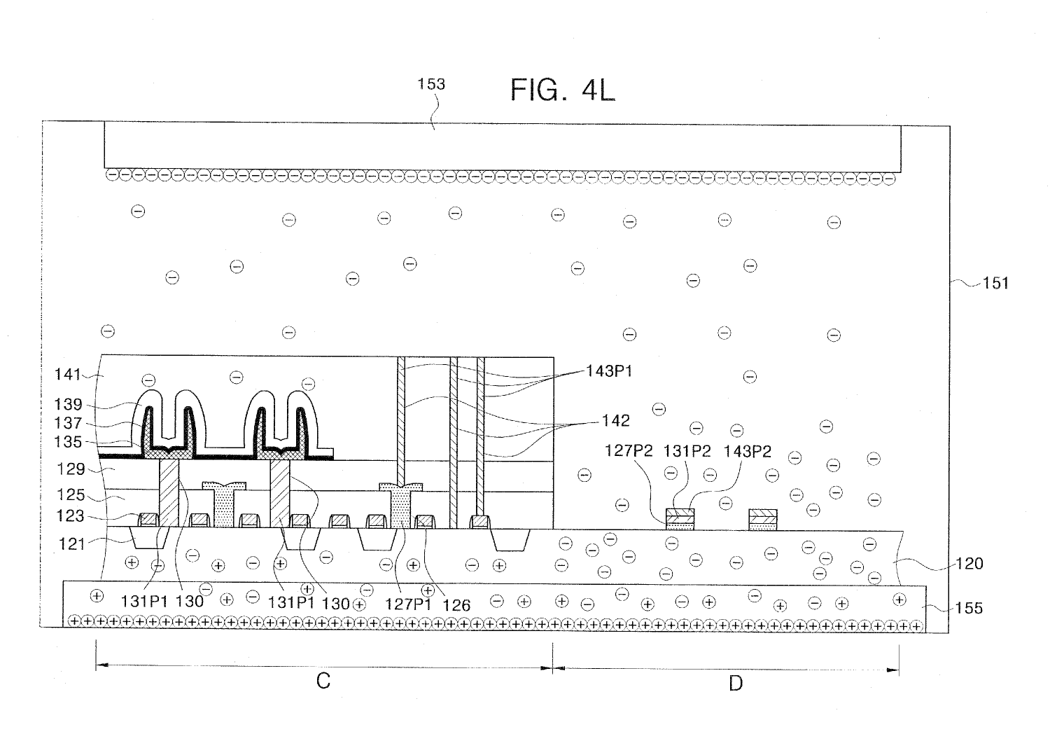

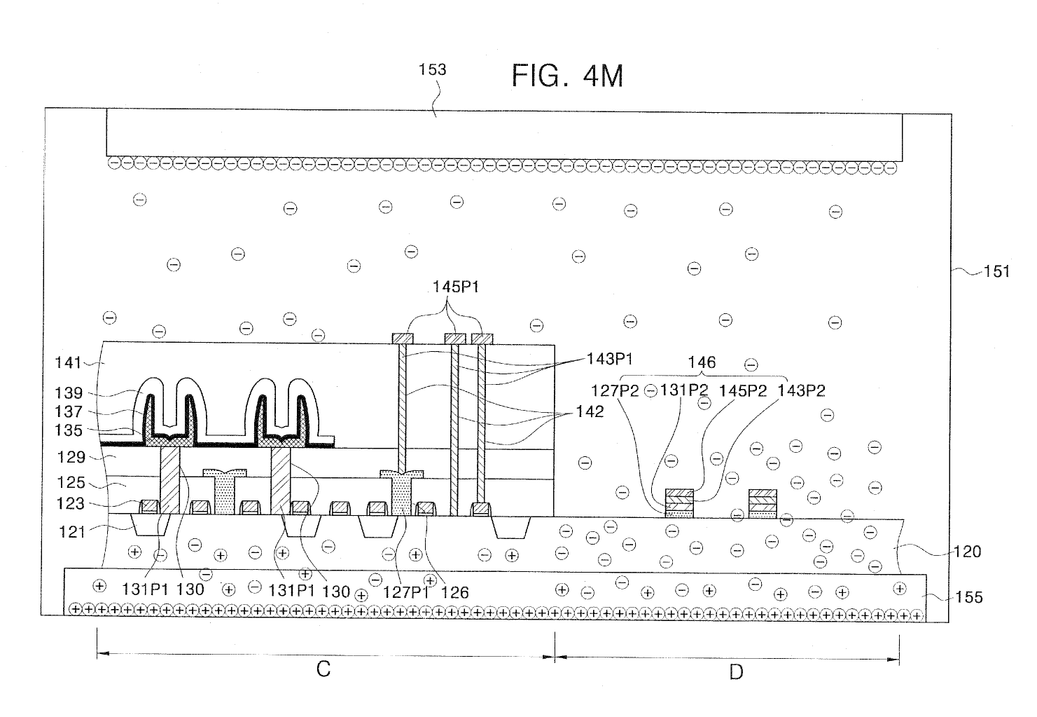

FIG. 3 is a plan diagram illustrating part of a semiconductor wafer in accordance with some embodiments of the invention. FIGS. 4A through 4M are cross-sectional diagrams, taken along line II-II′ of FIG. 3, which illustrate exemplary processes in a method for preventing charge-up in a plasma process in accordance with some embodiments of the invention.

As shown in FIG. 3, semiconductor chip regions C and scribe line regions D adjacent to the semiconductor chip regions C are defined on a semiconductor wafer 120. An interlayer insulating layer pattern (not illustrated) is disposed on the semiconductor wafer 120 to cover the semiconductor chip regions C and to expose the scribe line regions D. A conductive pattern (not illustrated) is disposed to contact a part of the semiconductor chip regions C through the interlayer insulating layer pattern, and conductive auxiliary patterns 145P2 covering a part of the exposed scribe line regions D are disposed. The insulating layer and the conductive pattern/conductive auxiliary patterns 145P2 are sequentially stacked.

As shown in FIG. 4A, semiconductor chip regions C and scribe line regions D are defined on a semiconductor wafer 120. Isolation layers 121 are formed on the wafer 120 by a well-known STI process. Gates 123 are formed on the wafer having the isolation layers 121. Here, sources/drains are omitted for convenience. The isolation layers 121 and the gates 123 are selectively formed in the semiconductor chip regions C of the wafer.

A first interlayer insulating layer is formed on the semiconductor wafer having the gates 123 in the plasma process chamber 151. The first interlayer insulating layer is formed of a HDP oxide layer. Alternatively, the first interlayer insulating layer may be formed of an HTO layer instead of the HDP oxide layer.

A first interlayer insulating layer pattern 125 is formed on the semiconductor wafer having the gates 123 by selectively etching the first interlayer insulating layer in the plasma process chamber 151. The first interlayer insulating layer pattern 125 is formed to cover the semiconductor chip regions C of the wafer and expose the scribe line regions D of the wafer. More specifically, the wafer having the first interlayer insulating layer is disposed in the plasma process chamber 151, etching gases and high-frequency energy are supplied, and the gases are ionized by the energy and selectively react with the first interlayer insulating layer to form the first interlayer insulating layer pattern 125. The selective etching of the first interlayer insulating layer may be performed by a plasma etching process in the plasma process chamber 151 or by a well-known etching process.

As shown in FIG. 4B, first contact holes 126 are formed to expose a prescribed region of the wafer in the semiconductor chip regions C by again selectively plasma etching the first interlayer insulating layer pattern 125 in the plasma process chamber 151. Here, during etching the interlayer insulating layer pattern 125, large quantities of electric charge generated by the plasma etching are discharged through the exposed scribe line regions D. Therefore, accumulation of a large amount of electric charge near the conductive gates 123 in the semiconductor chip regions C may be prevented.

As shown in FIG. 4C, a first conductive layer 127 is formed on the wafer having the first contact holes 126 in the plasma process chamber 151. The first conductive layer 127 may be formed by a PECVD process. When the first conductive layer 127 is formed by the PECVD process, a large amount of charge generated by the process may be discharged through a first conductive layer of the scribe line regions D. The first conductive layer 127 may include a tungsten layer. Before forming the first conductive layer 127, a barrier metal layer (not illustrated) may be formed. The barrier metal layer may include a TiN layer formed by a PECVD process.

As shown in FIG. 4D, the first conductive layer is selectively etched with plasma in the plasma process chamber 151 to form bit lines 127P1 covering the first contact holes 126 in the semiconductor chip regions C of the wafer, and first conductive auxiliary patterns 127P2 covering some parts of the scribe line regions D. The first conductive auxiliary patterns 127P2 are formed in lines in the scribe line regions D. At least one of the first conductive auxiliary patterns 127P2 is disposed in the scribe line regions D. Electric charges generated by the plasma etching of the first conductive layer may be discharged to a lower portion of the wafer through the first conductive layer of the scribe line regions D before the first conductive layer is completely etched. Therefore, accumulation of electric charge in the semiconductor chip regions C of the wafer may be prevented.

Referring to FIG. 4E, a second interlayer insulating layer is formed on the wafer having the first conductive auxiliary patterns 127P2 and the bit lines 127P1 in the plasma process chamber 151. The second interlayer insulating layer, like the first interlayer insulating layer, may include an oxide layer such as an HTO layer or a HDP oxide layer. The second interlayer insulating layer is etched to from the second interlayer insulating layer pattern 129, which covers the semiconductor chip regions C of the wafer and exposes the first conductive auxiliary patterns 127P2 of the scribe line regions D. Here, a plasma or conventional etching process may be performed to etch the second interlayer insulating layer.

As shown in FIG. 4F, the second interlayer insulating layer pattern 129 is etched again with plasma in the plasma process chamber 151, thereby forming second contact holes 130 which partially expose the wafer in the semiconductor chip regions C. Here, a large amount of electric charge generated by the plasma etching of the second interlayer insulating layer pattern 129 is discharged to a lower portion of the wafer through the first conductive auxiliary patterns 127P2 in the scribe line regions C. Therefore, accumulation of electric charge on the wafer in the semiconductor chip regions C may be prevented.

As shown in FIG. 4G, a second conductive layer 131 is formed on the wafer having the second contact holes 130. The second conductive layer 131 may include a multi-crystalline silicon layer or a metal layer. The metal layer is formed by a PECVD process.

As shown in FIG. 4H, the second conductive layer is etched with plasma to form buried contact plugs 131P1 covering the second contact holes 130 of the semiconductor chip regions C, and second conductive auxiliary patterns 131P2 covering the first conductive auxiliary patterns 127P2.

As shown in FIG. 4I, a capacitor is formed by sequentially forming a storage node 135, a dielectric layer 137, and a plate 139 on the wafer having the second conductive auxiliary patterns 131P2 and the buried contact plugs 131P1. At least one part of the storage node 135 is electrically connected to the buried contact plugs 131P2. A third interlayer insulating layer is formed on the wafer having the capacitor. A third interlayer insulating layer pattern 141 is formed by selectively etching the third interlayer insulating layer in the plasma process chamber 151. The third interlayer insulating layer pattern 141 is formed to cover the wafer in the semiconductor regions C and expose the second conductive auxiliary patterns 131P2 in the scribe line regions D. Here, plasma etching in the plasma process chamber 151 or some other known etching processes may be performed to selectively etch the third interlayer insulating layer.

As shown in FIG. 4J, the third interlayer insulating layer pattern 141 is selectively etched with plasma in the plasma process chamber 151 to form third contact holes 142 which each expose the bit lines 127P1, a part of the wafer, and the gate 123. Here, a large amount of electric charge generated by the plasma etching of the third interlayer insulating layer pattern 141 is discharged to a lower portion of the wafer through the first and second conductive auxiliary patterns 127P2 and 131P2 disposed in the scribe line regions D. Therefore, accumulation of a large amount of electric charge generated by the plasma etching of the third interlayer insulating layer pattern 141 in the semiconductor chip regions C may be prevented.

As shown in FIG. 4K, a fourth conductive layer 143 is formed on the wafer having the third contact holes 142 in the plasma process chamber 151. The fourth conductive layer 143 is formed by a PECVD process. The fourth conductive layer 143 is formed of a metal layer. As shown in FIG. 4L, the fourth conductive layer 143 is etched with plasma in the plasma process chamber 151 to form plugs 143P1 covering each of the third contact holes 142, and third conductive auxiliary patterns 143P2 covering the second conductive auxiliary patterns 131P2 of the scribe line regions D.

As shown in FIG. 4M, a fourth conductive layer (not illustrated) is formed on the wafer having the plugs 143P1 and the third conductive auxiliary patterns 143P2. The fourth conductive layer is etched with plasma to form metal patterns 145P1 covering the plugs 143P1 in the semiconductor chip regions C, and fourth conductive auxiliary patterns 145P2 covering the third conductive auxiliary patterns 143P2 in the scribe line regions D.

Meanwhile, reference numeral 146 in FIG. 4M denotes a conductive auxiliary pattern including the first conductive auxiliary pattern 127P2, the second conductive auxiliary pattern 131P2, the third conductive auxiliary pattern 143P2, and the fourth conductive auxiliary pattern 145P2 stacked in sequence. At least one of the conductive auxiliary patterns 146 may be disposed in the scribe line regions D. Because the conductive auxiliary pattern 146 has a tower-like stacked structure, the conductive auxiliary pattern 146 has a function that is similar to a lightning rod, allowing large amounts of excess charge to be discharged to a lower portion of the wafer.

Moreover, according to the illustrated embodiments of the invention, the rest of the scribe line regions are opened by etching the regions excluding a test pattern, an alignment key, and the like formed on the wafer, and then conductive auxiliary patterns are formed only in the opened scribe line regions.

According to embodiments of the invention, an interlayer insulating layer pattern is formed on the wafer to expose the scribe line regions, and then a contact hole is formed in a semiconductor chip region of the interlayer insulating layer pattern by plasma etching process. This enables a large amount of electric charge generated by the plasma etching to be discharged through the exposed scribe line region. Also, the invention has a conductive auxiliary pattern covering at least one part of the scribe line region through which a large amount of electric charge generated by plasma etching may be discharged.

Accordingly, embodiments of the invention prevent the charge-up phenomenon in which a large amount of electric charge accumulates near conductive patterns as a result of plasma processing, thereby enhancing product reliability. In addition, embodiments of the invention provide a semiconductor wafer that prevent the charge-up phenomenon.

The invention may be practiced in many ways. What follows are exemplary, non-limiting descriptions of some embodiments of the invention.

According to some embodiments, a method for preventing plasma charge-up of a semiconductor wafer includes: a) providing the semiconductor wafer having a semiconductor chip region and a scribe line region defined thereon, b) forming an interlayer insulating layer pattern on the wafer to expose the scribe line region, c) forming a contact hole exposing a part of the semiconductor chip region, and d) discharging electric charge generated by the plasma etching process through the exposed scribe line region during etching the interlayer insulating layer pattern.

The method may further include, after process d), e) forming a conductive layer on the wafer having the contact hole; and f) selectively etching the conductive layer with plasma, forming a conductive pattern covering the contact hole, and forming a conductive auxiliary pattern covering at least one part of the scribe line region.

The conductive pattern may be a bit line, a plug, or a metal interconnection. The conductive auxiliary pattern may be formed in the shape of a line covering at least one part of the scribe line region.

Also, the conductive auxiliary pattern may be formed in a multi-layered structure by repeatedly performing processes b) through e).

According to some embodiments of the invention, a semiconductor wafer includes a first interlayer insulating layer pattern covering a semiconductor chip region and exposing a scribe line region between the semiconductor chip regions, a first conductive pattern electrically connected to the semiconductor chip region through the first interlayer insulating layer pattern, and a first conductive auxiliary pattern covering at least one part of the exposed scribe line region.

The first conductive pattern and the first conductive auxiliary pattern may be patterned from the same layer.

The first conductive pattern may be a bit line, a plug, or a metal interconnection.

At least one of the first conductive auxiliary patterns may be disposed in the scribe line region.

The first conductive auxiliary pattern may be formed in the shape of a line covering at least one part of the scribe line region.

The wafer may further include a second interlayer insulating layer pattern exposing the scribe line region including the first conductive auxiliary pattern in the semiconductor chip region of the wafer having the first conductive pattern, a second conductive pattern electrically connected to the semiconductor chip region through the first and second interlayer insulating layer pattern, and a second conductive auxiliary pattern deposited on the first conductive auxiliary pattern

The second conductive pattern and the second conductive auxiliary pattern may be patterned from the same layer.

The first conductive pattern may be a bit line and the second conductive pattern may be a plug.

In alternative embodiments, the first conductive pattern may be a plug and the second conductive pattern may be a metal interconnection.

At least one of the first and second conductive auxiliary patterns may be disposed in the scribe line region.

According to other embodiments of the invention, a semiconductor wafer includes a first interlayer insulating layer pattern covering a semiconductor chip region and exposing a scribe line region between the semiconductor chip regions, a first conductive auxiliary pattern covering at least one part of the exposed scribe line region, and a bit line electrically connected to the semiconductor chip region through the first interlayer insulating layer pattern; a second interlayer insulating layer pattern exposing the scribe line region including the first conductive auxiliary pattern in the semiconductor chip region of the wafer having the bit line, a second conductive auxiliary pattern deposited on the first conductive auxiliary pattern, a buried contact plug electrically connected to the semiconductor chip region through the first and second interlayer insulating layer pattern, and a capacitor that is disposed on the second interlayer insulating layer pattern and connected to the buried contact plug.

The bit line and the first conductive auxiliary pattern may be patterned from the same layer.

Also, the buried contact plug and the second conductive auxiliary pattern may be patterned from the same layer.

Furthermore, the buried contact plug and the second conductive auxiliary pattern may be metal layers.

The semiconductor chip region of the wafer having the capacitor may further include a third interlayer insulating layer pattern exposing a scribe line region including the second conductive auxiliary pattern, a third conductive auxiliary pattern deposited on the second conductive auxiliary pattern, a plug that is electrically connected to the semiconductor chip region through the first, second and third interlayer insulating layer pattern, a fourth conductive auxiliary pattern deposited on the third conductive auxiliary pattern, and a metal interconnection electrically connected to the plug on the third interlayer insulating layer pattern.

The plug and the third conductive auxiliary pattern may be patterned from the same layer. Also, the metal interconnection and the fourth conductive auxiliary pattern may be patterned from the same layer.

Exemplary embodiments of the invention have been disclosed herein and, although specific terms are employed, they are used and are to be interpreted in a generic and descriptive sense only and not for purpose of limitation. Accordingly, it will be understood by those of ordinary skill in the art that various changes in form and details may be made to the exemplary embodiments without departing from the spirit and scope of the invention as set forth in the following claims.

1. A method for preventing plasma charge-up of a semiconductor wafer, comprising:
a) defining a semiconductor chip region and a scribe line region on a semiconductor wafer;
b) forming an interlayer insulating layer pattern on the wafer, the interlayer insulating layer pattern exposing the scribe line region;
c) plasma etching the interlayer insulating layer pattern to form a contact hole that exposes the semiconductor chip region; and
d) during the plasma etching, discharging an electric charge generated by the plasma etching through the scribe line region.

2. The method of claim 1, further comprising, after step d):
e) covering the wafer and the contact hole with a conductive layer; and
f) plasma etching the conductive layer to form a conductive pattern that covers the contact hole and to form a conductive auxiliary pattern that covers a part of the scribe line region.

3. The method of claim 2, wherein plasma etching the conductive layer to form the conductive pattern comprises plasma etching the conductive layer to form one selected from the group consisting of a bit line, a plug, and a metal interconnection.

4. The method of claim 2, wherein plasma etching the conductive layer to form the conductive auxiliary pattern comprises plasma etching the conductive layer to form a line-shaped region that covers the part of the scribe line region.

5. The method of claim 2, further comprising forming a multi-layered conductive auxiliary pattern by sequentially repeating processes b) through f).

6. A semiconductor wafer comprising:
a first interlayer insulating layer pattern, the first interlayer insulating layer pattern covering semiconductor chip regions of the semiconductor wafer and exposing a scribe line region between the semiconductor chip regions;
a first conductive pattern that is electrically connected to the semiconductor chip regions through the first interlayer insulating layer pattern; and
a first conductive auxiliary pattern that covers a part of scribe line region.

7. The semiconductor wafer of claim 6, wherein the first conductive pattern and the first conductive auxiliary pattern are patterned from the same layer.

8. The semiconductor wafer of claim 6, wherein the first conductive pattern comprises one selected from the group consisting of a bit line, a plug, and a metal interconnection.

9. The semiconductor wafer of claim 6, the first conductive auxiliary pattern disposed in the scribe line region.

10. The semiconductor wafer of claim 6, the first conductive auxiliary pattern comprising a line-shaped structure.

11. The semiconductor wafer of claim 6, further comprising:
a second interlayer insulating layer pattern disposed on the first interlayer insulating layer pattern, the second interlayer insulating layer pattern exposing the scribe line region and the first conductive auxiliary pattern;
a second conductive pattern that is electrically connected to the semiconductor chip region through the first and second interlayer insulating layer pattern; and
a second conductive auxiliary pattern disposed on the first conductive auxiliary pattern.

12. The semiconductor wafer of claim 11, wherein the second conductive pattern and the second conductive auxiliary pattern are patterned from the same layer.

13. The semiconductor wafer of claim 11, wherein the first conductive pattern is a bit line and the second conductive pattern is a plug.

14. The semiconductor wafer of claim 11, wherein the first conductive pattern is a plug and the second conductive pattern is a metal interconnection

15. The semiconductor wafer of claim 11, wherein at least one of the first and second conductive auxiliary patterns are disposed in the scribe line region.

16. A semiconductor wafer comprising:
a first interlayer insulating layer pattern that covers semiconductor chip regions of the semiconductor wafer and that exposes a scribe line region of the semiconductor wafer, the scribe line region between the semiconductor chip regions;
a first conductive auxiliary pattern that covers a portion of the scribe line region;
a bit line that is electrically connected to the semiconductor chip region through the first interlayer insulating layer pattern;
a second interlayer insulating layer pattern disposed on the first interlayer insulating layer pattern, the second interlayer insulating layer pattern exposing the scribe line region and the first conductive auxiliary pattern;
a second conductive auxiliary pattern deposited on the first conductive auxiliary pattern;
a buried contact plug that is electrically connected to the semiconductor chip region through the first and second interlayer insulating layer pattern; and
a capacitor disposed on the second interlayer insulating layer pattern and connected to the buried contact plug.

17. The semiconductor wafer of claim 16, wherein the bit line and the first conductive auxiliary pattern are patterned from a first layer.

18. The semiconductor wafer of claim 16, wherein the buried contact plug and the second conductive auxiliary pattern are patterned from a second layer.

19. The semiconductor wafer of claim 18, wherein the second layer consists of a metal layer.

20. The semiconductor wafer of claim 16, further comprising:
a third interlayer insulating layer pattern disposed on the second interlayer insulating layer pattern, the third interlayer insulating layer pattern exposing the second conductive auxiliary pattern;
a third conductive auxiliary pattern deposited on the second conductive auxiliary pattern;
a plug electrically connected to the semiconductor chip regions through the first, second, and third interlayer insulating layers; and
a fourth conductive auxiliary pattern deposited on the third conductive auxiliary pattern; and
a metal interconnection electrically connected to the plug on the third interlayer insulating layer.

21. The semiconductor wafer according to claim 20, wherein the plug and the third conductive auxiliary pattern are patterned from a third layer.

22. The semiconductor wafer according to claim 20, wherein the metal interconnection and the fourth conductive auxiliary pattern are patterned from a fourth layer.
